(19) United States
(12) Patent Application Publication
(10) Pub. No.: US 2012/0219860 A1
(43) Pub. Date: Aug. 30, 2012

(54) HETERO-NANOSTRUCTURE MATERIALS FOR USE IN ENERGY-STORAGE DEVICES AND METHODS OF FABRICATING SAME

(75) Inventors: Dunwei Wang, Newton, MA (US); Sa Zhou, Chestnut Hill, MA (US)

(73) Assignee: THE TRUSTEES OF BOSTON COLLEGE

(21) Appl. No.: 13/504,334

(22) PCT Filed: Oct. 25, 2010
(86) PCT No.: PCT/US2010/053951

§ 371 Date: Apr. 26, 2012

Related U.S. Application Data
(60) Provisional application No. 61/254,901, filed on Oct. 26, 2009.

(51) Int. Cl. H01M 4/58; H01M 4/50; B05D 5/12; C23C 16/42; H01M 4/48; H01B 1/04; B82Y 40/00; B82Y 30/00

(52) U.S. Cl. 429/220; 429/231.5; 429/223; 429/221; 429/224; 252/500; 252/520.22; 427/58; 427/126.1; 977/810; 977/891

(57) ABSTRACT

The embodiments disclosed herein relate to hetero-nano structure materials for use in energy-storage devices, and more particularly to the fabrication of hetero-nanostructure materials and the use of the hetero-nano structure materials as battery electrodes. In an embodiment, a Si/TiSi₂ electrode 1000 of the present disclosure includes a plurality of Si/TiSi₂ nanonets 1001 formed on a surface of a supporting substrate 1100, wherein each of the Si/TiSi₂ nanonets 1001 includes a plurality of connected and spaced-apart nanobeams linked together at an about 90-degree angle, wherein the nanobeams are composed of a conductive silicide core having a silicon particulate coating.

### RELATED APPLICATIONS

This application claims the benefit of and priority to U.S. Provisional Patent Application No. 61/254,901, filed on Oct. 26, 2009, the entirety of this application is hereby incorporated herein by reference.

### FIELD

The embodiments disclosed herein relate to hetero-nanostructure materials for use in energy-storage devices, and more particularly to the fabrication of hetero-nanostructure materials and the use of the hetero-nanostructure materials as battery electrodes.

### BACKGROUND

Lithium-ion batteries are a type of rechargeable battery in which lithium ions move from the negative electrode (anode) to the positive electrode (cathode) during discharge, and from the cathode to the anode during charge. Lithium-ion batteries are common in portable consumer electronics because of their high energy-to-weight ratios, lack of memory effect, and slow self-discharge when not in use. In addition to consumer electronics, lithium-ion batteries are increasingly used in defense, automotive, and aerospace applications due to their high energy density. Commercially, the most popular material for the anode for a lithium-ion battery is graphite. The cathode is generally one of three materials: a layered oxide (such as lithium cobalt oxide), one based on a polyanion (such as lithium iron phosphate), or a spinel (such as lithium manganese oxide), although materials such as TiS₂ (titanium disulfide) have been used. Depending on the choice of material for the anode, cathode, and electrolyte, the voltage, capacity, life, and safety of a lithium-ion battery can change dramatically.

Improvements for Li-ion batteries focus on several areas, and often involve advances in nanotechnology and microstructures. Technology improvements include, but are not limited to, increasing cycle life and performance (decreases internal resistance and increases output power) by changing the composition of the material used in the anode and cathode, along with increasing the effective surface area of the electrodes and changing materials used in the electrolyte and/or combinations thereof; improving capacity by improving the structure to incorporate more active materials; and improving the safety of lithium-ion batteries.

### SUMMARY

Hetero-nanostructure materials for use as battery electrodes and methods of fabricating same are disclosed herein.

According to aspects illustrated herein, there is provided a hetero-nanostructure material that includes a plurality of connected and spaced-apart nanobeams linked together at an about 90-degree angle, wherein the nanobeams are composed of a conductive silicide core having a particulate coating.

According to aspects illustrated herein, there is provided an electrode that includes a plurality of Si/TiSi₂ nanonets formed on a surface of a supporting substrate, wherein each of the Si/TiSi₂ nanonets comprise a plurality of connected and spaced-apart nanobeams linked together at an about 90-degree angle, wherein the nanobeams are composed of a conductive silicide core having a silicon particulate coating.

According to aspects illustrated herein, there is provided a method of fabricating a hetero-nanostructure material that includes performing chemical vapor deposition in a reaction chamber at a first temperature for a first period of time so as to fabricate a two-dimensional conductive silicide, wherein one or more gas or liquid precursor materials carried by a carrier gas stream react to form a nanostructure having a mesh-like appearance and including a plurality of connected and spaced-apart nanobeams linked together at an about 90-degree angle; halting the flow of the one or more gas or liquid precursor materials while maintaining the carrier gas stream; cooling the reaction chamber to a second temperature; and introducing the gas precursor back into the reaction chamber for a second period of time so as to coat the two-dimensional conductive silicide with particulates so as to fabricate the hetero-nanostructure material.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 is a schematic representation of an embodiment of a single nanonet (NN) of a Si/TiSi₂ hetero-nanostructure material of the present disclosure.

FIGS. 2A, 2B, 2C and 2D show electron micrographs of an embodiment of Si/TiSi₂ hetero-nanostructure material of the present disclosure. FIG. 2A is a scanning electron micrograph (SEM) of the Si/TiSi₂ hetero-nanostructure material. FIG. 2B is a transmission electron micrograph (TEM) showing a single NN of the Si/TiSi₂ hetero-nanostructure material of FIG. 2A. FIG. 2C is an enlarged TEM and the selected area electron diffraction pattern of the Si/TiSi₂ hetero-nanostructure material of FIG. 2B revealing the crystallinity nature of the TiSi₂ nanobeam core and the particulate Si coating. FIG. 2D is a lattice-resolved TEM showing the crystallinity nature of the TiSi₂ nanobeam core and the particulate Si coating.

FIGS. 3A and 3B show observed electrochemical potential spectra of a TiSi₂ nanostructure material and a Si/TiSi₂ hetero-nanostructure material of the present disclosure using electrochemical potential spectroscopy (EPS). FIG. 3A shows the full EPS spectra of the TiSi₂ nanostructure material and the Si/TiSi₂ hetero-nanostructure material. FIG. 3B shows only the portion corresponding to charging, with arbitrary offsets in the y-axis. The peaks in the shaded region correspond to Li⁺ insert to TiSi₂. The peak denoted by ▪ is due Li⁺ insertion into c-Si, and that by is due to Li⁺ insertion into a-Si.

FIG. 4 illustrates the capacity life of Si/TiSi₂ heterostructure material at different potential ranges. Capacity retention is improved by choosing a higher cut-off potential. Charging rate: 8400 mA/g.

FIGS. 5A, 5B and 5C show potential (V) versus capacity (mAh/g) curves for the first cycle (FIG. 5A), the second to fifth cycles (FIG. 5B) and the first and second cycles (FIG. 5C) of the charge-discharge process of a Si/TiSi₂ hetero-nanostructure material of the present disclosure.

FIG. 6 show charge capacity and Coulombic efficiency of a Si/TiSi₂ hetero-nanostructure material of the present disclosure with 8400 mA/g charge/discharge rate tested between 0.150 and 3.00 V.

FIG. 7 shows how the specific capacity changes with the charging/discharging rate.

FIGS. 8A and 8B show TEMs of Si/TiSi₂ hetero-nanostructure materials of the present disclosure, revealing the crystalline nature of both the TiSi₂ core and the Si shell. FIG. 8A shows TEM of as-prepared Si/TiSi₂ hetero-nanostructure materials. FIG. 8B shows TEM after 20 cycles of continuous charging/discharging, the Si shell is transformed into amorphous while the crystalline nature of the TiSi₂ core is preserved. Scale bars: 20 nm.

FIG. 9 shows the superior conductivity of the TiSi₂ core survives the charging/discharging processes.

FIG. 10 shows the influence of the morphology of Si on the specific capacity and the capacity life. The nature of the coating has a notable impact on the capacity life of the resulting anode. Particulate Si coating, as shown in FIGS. 2B, 2C, 8A and 8B allows for volumetric expansion upon Li⁺ insertion, yielding long capacity life. Uniform Si coating, on the other hand, leads to faster capacity fading due to the pulverization effect.

FIGS. 11A and 11B show schematic illustrations of an embodiment of a Si/TiSi₂ electrode of the present disclosure. FIG. 11A is a perspective view of the Si/TiSi₂ electrode. FIG. 11B is a side view of the Si/TiSi₂ electrode.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

As used herein, the term “coulombic efficiency”, “QE” or “ampere-hour efficiency” refers to the ratio, usually expressed as a percentage, of the ampere-hours removed from a battery during a discharge to the ampere-hours required to restore the initial capacity.

As used herein, the term “anode” refers to an electrode with which the reactions by the electrolyte are of lower potentials.

As used herein, the term “capacity” refers to the amount of charge, usually expressed in ampere-hours, that can be withdrawn from a fully charged battery under specified conditions.

As used herein, the term “cathode” refers to an electrode with which the reactions by the electrolyte are of higher potentials.

As used herein, the term “charge rate” refers to the current applied to charge a battery to restore its available capacity.

As used herein, the term “cycle” refers to a single charge-discharge of a battery.

As used herein, the term “cycle life” refers to the number of cycles that can be obtained from a battery before it fails to meet selected performance criteria.

As used herein, the term “discharge rate” refers to the current at which a battery is discharged. The current can be expressed in ampere-hours.

As used herein, the term “efficiency” refers to the fraction, usually expressed in percentage, of the available output from a battery that is achieved in practice.

As used herein, the term “electrode” refers to an electronic conductor which acts as a source or sink of electrons which are involved in electrochemical reactions.

As used herein, the term “electrode potential” refers to the voltage developed by a single electrode, either positive or negative.

As used herein, the term “energy-storage device” refers to a device that stores some form of energy that can be drawn upon at a later time to perform some useful operation. Examples of energy-storage devices include, but are not limited to, batteries, flywheels, and ultracapacitors.

As used herein, the term “lithiation” refers to the treatment (insertion) with lithium (“Li”) or one of its compounds.

As used herein, the term “negative electrode” refers to the electrode in an electrolytic cell that has the lower potential.

As used herein, the term “positive electrode” refers to the electrode in an electrolytic cell that has the higher potential.

As used herein, the term “specific capacity” refers to the capacity output of a battery per unit weight, usually expressed in Ah/kg.

As used herein, the “state of charge” or “SOC” is defined as a percentage of the capacity that the battery exhibits between a lower voltage limit at which the battery is fully discharged at equilibrium, and an upper voltage limit at which the battery is fully charged at equilibrium. Thus a 0% SOC corresponds to the fully discharged state and 100% SOC corresponds to the fully charged state.

High capacity, long cycle life and fast charge/discharge rate lithium-ion (Li⁺) batteries are important for today's mobile society and hybrid vehicles. With the theoretical specific capacity limit of 4200 mAh/g, crystalline silicon (“c-Si”) represents a particularly appealing candidate as the electrode material for Li-ion batteries. However, the application of silicon-based electrodes is limited by the poor charge transport ability and unmanageable volumetric expansion of silicon upon Li⁺ insertion (lithiation). These deficiencies result in drastic and fast capacity fading due to structural and electronic degradation, dampening the prospect of exploiting the high capacity that silicon possesses. To solve these challenges, Si-based nanostructures such as nanoparticles, thin films and nanowires have been studied. Similar to cases where bulk Si is involved, pulverization and electronic contact degradation keep the capacity life of anodes made of nanoparticles that contain Si short. Thin film or amorphous silicon (“a-Si”) offers high specific capacity, good capacity retention and fast charge/discharge rate, but it suffers a major drawback of low active material content. While the anisotropic nature of Si nanowires acts positively to accommodate the volumetric changes upon Li⁺ insertion and extraction, the complete lithiation of Si nanowires nevertheless impedes charge transport in the longitudinal direction, limiting the charge/discharge rate and capacity life. Evidently, the realization of high capacity, long capacity life and fast charge/discharge rate requires the ability to accommodate the volumetric change while maintaining superior charge transport, a goal best met by composite nanomaterials. Carbon nanotubes, nanofibers and graphene, for instance, have been studied as the inactive component to facilitate charge transport. Nevertheless, how to effectively interface Si with carbon remains a challenge.

In an embodiment, the present disclosure provides a hetero-nanostructure material comprising two-dimensional TiSi₂ nanonets having a particulate Si coating. The high conductivity and the structural integrity of the TiSi₂ nanonet core permit reproducible Li⁺ insertion and extraction into and from the Si coating. In an embodiment, this hetero-nanostructure material was tested as the anode material for Li⁺ storage. At a charge/discharge rate of 8400 mA/g, specific capacities >1000 mAh/g were measured. Only an average of 0.1% capacity fade per cycle was observed between the 20th and the 100th cycles. The combined high capacity, long capacity life, and fast charge/discharge rate represent one of the best anode materials that have been reported. The remarkable performance was enabled by the capability to preserve the crystalline TiSi₂ core during the charge/discharge process. This achievement demonstrates the potency of this hetero-nanostructure material as an electrode material for energy storage.

In an embodiment, a hetero-nanostructure material of the present disclosure combines highly conductive complex TiSi₂ nanonets (NNs) with Si coating (as termed herein, Si/TiSi₂ hetero-nanostructure material). In an embodiment, the disclosed hetero-nanostructure materials tackle the deficiencies described above, and are therefore appealing materials for rechargeable batteries. In an embodiment, the disclosed hetero-nanostructure materials tackle the deficiencies described above, and are therefore appealing materials for high performance Li and Li-ion battery electrodes. In an embodiment, the disclosed hetero-nanostructure materials tackle the deficiencies described above, and are therefore appealing materials for high performance Li-ion battery anodes. In some embodiments of the present disclosure, hetero-nanostructure materials include highly conductive TiSi₂ nanobeam cores having a silicon coating. In an embodiment, the silicon coating is a particulate coating. In an embodiment, the silicon coating is a smooth film coating. The TiSi₂ nanobeam cores act as the structural support as well as the component to facilitate effective charge transport, while the particulate silicon coating acts as the medium to react with Li⁺. Compared to conventional structures, the Si/TiSi₂ hetero-nanostructure materials of the present disclosure offers distinct advantages, including, but not limited to, ease of interfacing Si with TiSi₂, and superior charge transport through TiSi₂. The former is enabled by the similarities between TiSi₂ and Si crystal structures, and the latter is ensured by the capability to selectively insert Li⁺ into Si only. As illustrated herein, fast charge/discharge without significant capacity fading can be achieved using the disclosed hetero-nanostructure materials. For example, at a charging rate of 8400 mA/g, greater than 99% capacity retention per cycle has been observed at the level of >1000 mAh/g over 100 cycles.

Although the present disclosure focuses on the use of Si—TiSi₂ hetero-nanostructure materials as high performance Li-ion battery anodes, it should be apparent that other combinations of materials can be used to form the core or shells of a hetero-nanostructure material, and their use in other energy-storage devices are contemplated. Materials that can be used to replace Si include, but are not limited to, Ge, SnO₂, TiO₂, MnO₂, WO₃, V₂O₅, CuO, NiO, Co₃O₄ and TiS₂. Materials that can replace TiSi₂ include, but are not limited to, nickel silicide (NiSiₓ), iron silicide (FeSiₓ), platinum silicide, chromium silicide, cobalt silicide (CoSiₓ), molybdenum silicide and tantalum silicide, as well as various other conductive nanostructures. In an embodiment, a hetero-nanostructure material of the present disclosure is Si/NiSiₓ. In an embodiment, a hetero-nanostructure material of the present disclosure is Si/CoSiₓ. In an embodiment, a hetero-nanostructure material of the present disclosure is SnO₂/TiSiₓ.

Silicides are highly conductive materials formed by alloying silicon with selected metals. Titanium silicide (TiSi₂) is an excellent electronic material and is one of the most conductive silicides (resistivity of about 10 micro-ohm-centimeters (μΩ·cm)). Better charge transport offered by complex structures of nanometer-scaled TiSi₂ is desirable for nanoelectronics. Capabilities to chemically synthesize TiSi₂ are therefore appealing. Synthetic conditions required by the two key features of complex nanostructures, low dimensionality and complexity, however, seem to contradict each other. Growth of one-dimensional (1D) features involves promoting additions of atoms or molecules in one direction while constraining those in all other directions, which is often achieved either by surface passivation to increase energies of sidewall deposition (such as solution phase synthesis) or introduction of impurity to lower energies of deposition for the selected directions (most notably the vapor-liquid-solid mechanism). Complex crystal structures, on the other hand, require controlled growth in more than one direction. The challenge in making two-dimensional (2D) complex nanostructures is even greater as it demands more stringent controls over the complexity to limit the overall structure within two dimensions. The successful chemical syntheses of complex nanostructures have been mainly limited to three-dimensional (3D) ones. In principle, 2D complex nanostructures are less likely to grow for crystals with high symmetries, e.g. cubic, since various equivalent directions tend to yield a 3D complex structure; or that with low symmetries, e.g. triclinic, monoclinic or trigonal, each crystal plane of which is so different that simultaneous growths for complexity are prohibitively difficult.

According to aspects illustrated herein, a method is disclosed for fabricating a hetero-nanostructure material of the present disclosure. As potential candidates of electrodes for Li and Li-ion based battery technologies, the disclosed materials can be synthesized by gas phase reactions. This feature makes it possible to interface silicon with conductive nanostructures, which serve as the structural support and charge transporter. In an embodiment, a chemical vapor deposition (CVD) system is used for the fabrication of a hetero-nanostructure material of the present disclosure. In an embodiment, a chemical vapor deposition system is used for the fabrication of a core structure of nanobeams and for the deposition of a particulate layer on the core structure. In an embodiment, a chemical vapor deposition system is used for the fabrication of a core structure of nanobeams and a sputtering technique is used for the deposition of a particulate layer on the core structure. In an embodiment, a chemical vapor deposition system is used for the fabrication of a core structure of nanobeams and a cold-wall chemical vapor deposition system is used for the deposition of a particulate layer on the core structure. In an embodiment, a chemical vapor deposition system is used for the fabrication of a core structure of nanobeams and a plasma enhanced chemical vapor deposition system is used for the deposition of a particulate layer on the core structure.

In an embodiment, a CVD system is used for the fabrication of a hetero-nanostructure material of the present disclosure. The CVD system can have, for example, automatic flow and pressure controls. Flow of a precursor gas and a carrier gas are controlled by mass flow controllers, and fed to a growth (reaction) chamber at precise flow rates. The flow rate for the precursor gas is between about 20 standard cubic centimeters per minute (sccm) and about 100 sccm. In an embodiment, the flow rate for the precursor gas is about 50 sccm (10% in He) for growing TiSi₂ nanobeam cores. In an embodiment, the flow rate for the precursor gas is about 80 sccm (10% in He) for producing a uniform coating of Si nanoparticles of about 15 to about 20 nm in diameter on the TiSi₂ cores. In an embodiment, the precursor gas is present at a concentration ranging from about 1.3×10⁻⁶ mole/L to about 4.2×10⁻⁶ mole/L. In an embodiment, the precursor gas is present at a concentration of about 2.8±1×10⁻⁶ mole/L. The flow rate for the carrier gas is between about 80 standard cubic centimeters per minute (sccm) and about 130 sccm. In an embodiment, the flow rate for the carrier gas is about 100 sccm. A precursor liquid is stored in a cylinder and released to the carrier gas mass flow controller through a metered needle control valve. The flow rate for the precursor liquid is between about 1.2 sccm and 5 sccm. In an embodiment, the flow rate for the precursor liquid is about 2.5 sccm. In an embodiment, the flow rate for the precursor liquid is about 2.0 sccm. In an embodiment, the precursor liquid is present at a concentration ranging from about 6.8×10⁻⁷ mole/L to about 3.2×10⁻⁶ mole/L. In an embodiment, the precursor liquid is present at a concentration of about 1.1±0.2×10⁻⁶ mole/L. All precursors are mixed in a pre-mixing chamber prior to entering the reaction chamber. The pressure in the reaction chamber is automatically controlled and maintained approximately constant by the combination of a pressure transducer and a throttle valve. In an embodiment, the system is kept at a constant pressure of about 5 Torr during growth. The variation of the pressure during a typical growth is within 1% of a set point. All precursors are kept at room temperature before being introduced into the reaction chamber. A typical reaction lasts from about five minutes up to about twenty minutes. In an embodiment, the growth reaction lasts about fifteen minutes. The reaction chamber is heated by a horizontal tubular furnace to a temperature ranging from about 650° C. to about 685° C. In an embodiment, the reaction chamber is heated to a temperature of about 675° C. A typical reaction for producing a coating of Si nanoparticles on the TiSi₂ nanobeam cores lasts from about five minutes up to about twenty minutes. In an embodiment, the coating reaction lasts about twelve minutes. During a coating reaction, the reaction chamber is cooled to a temperature ranging from about 625° C. to about 660° C. In an embodiment, the reaction chamber is cooled to a temperature of about 650° C.

In an embodiment, the precursor liquid is a titanium containing chemical. Examples of titanium containing chemicals include, but are not limited to, titanium beams from high temperature (or electromagnetically excited) metal targets, titanium tetrachloride (TiCl₄), and titanium-containing organometallic compounds. In an embodiment, the precursor gas is a silicon containing chemical. Examples of silicon containing chemicals include, but are not limited to, silane (SiH₄), silicon tetrachloride (SiCl₄), disilane (Si₂H₆), other silanes, and silicon beams by evaporation. In an embodiment, the carrier gas is selected from the group consisting of hydrogen (H), hydrochloric acid (HCl), hydrogen fluoride (HF), chlorine (Cl₂), fluorine (F₂), and an inert gas.

In an embodiment, 2D conductive TiSi₂ nanostructure cores are spontaneously fabricated in the CVD system when the precursors react and/or decompose on a substrate in the growth chamber. This spontaneous fabrication occurs via a seedless growth, i.e., no growth seeds are necessary for the growth of the 2D conductive TiSi₂ nanostructures. Therefore, impurities are not introduced into the resulting nanostructures. The fabrication method is simple, no complicated pre-treatments are necessary for the receiving substrates. The growth is not sensitive to surfaces (i.e., not substrate dependent). No inert chemical carriers are involved (the carrier gas also participates the reactions). The substrates that the disclosed nanostructures can be grown on are versatile, so long as the substrate sustains the temperatures required for the synthesis. In an embodiment, the 2D conductive TiSi₂ nanostructures are grown on a transparent substrate. In an embodiment, the 2D conductive TiSi₂ nanostructures are grown on a titanium foil substrate. It is believed that due to the nature of the synthesis of the 2D conductive TiSi₂ nanostructures disclosed herein, a continuous synthesis process may be developed to allow for roll-to-roll production.

In an embodiment, a TiSi₂ nanostructure is composed of a plurality of nanobeams, approximately 25 nm wide and approximately 15 nm thick, all linked together by single crystalline junctions with about 90° angles. In an embodiment, the nanobeams are substantially perpendicular to each other. High resolution transmission electron microscopy (HRTEM) images and electron diffraction (ED) patterns of different regions of a nanobeam reveal that the entire nanobeam structure is single crystalline, including the 90° joints, the middle and the ends. The ends of the nanobeams are free of impurities. In an embodiment, loose ends of the nanobeam often bend on TEM supporting films, showing characteristics of nanobelts, and the thickness of a nanonet (NN) sheet (approximately 15 nm) is thinner than the width of the NN (approximately 25 nm).

In an embodiment, a complex Si/TiSi₂ hetero-nanostructure material of the present disclosure combines highly conductive two-dimensional (2D) complex nanonets with a lithiable coating. The hetero-nanostructure material can offer outstanding charge transport among branches that are linked by single crystalline junctions. In an embodiment, a complex Si/TiSi₂ hetero-nanostructure material of the present disclosure combines highly conductive two-dimensional (2D) complex nanowires with a lithiable coating. In an embodiment, a complex Si/TiSi₂ hetero-nanostructure material of the present disclosure combines highly conductive two-dimensional (2D) complex nanobelts with a lithiable coating. In an embodiment, a complex Si/TiSi₂ hetero-nanostructure material of the present disclosure combines highly conductive two-dimensional (2D) complex nanosheets with a lithiable coating. In an embodiment, a complex Si/TiSi₂ hetero-nanostructure material of the present disclosure combines highly conductive two-dimensional (2D) complex nanoparticles with a lithiable coating.

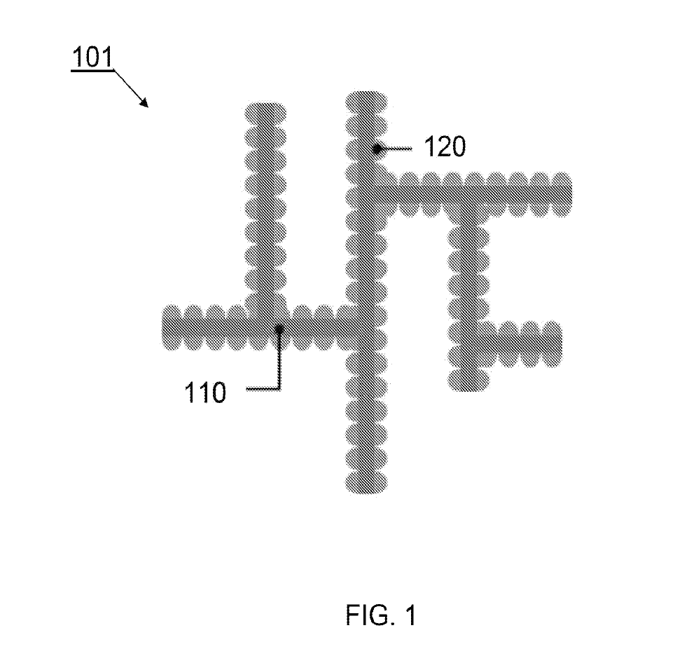

FIG. 1 shows a schematic representation of an embodiment of a single nanonet (NN) 101 of a Si/TiSi₂ hetero-nanostructure material of the present disclosure. The NN 101 comprises Si nanoparticles 120 on a TiSi₂ nanobeam core 110. In an embodiment, the TiSi₂ nanobeam core 110 functions as an inactive compound to support the Si nanoparticles 120 and facilitate charge transport. In an embodiment, the Si nanoparticles 120 functions as an active component to store and release lithium-ion (Li⁺). In an embodiment, the NN 101 includes a conductive core that does not participate in the lithiation process and a reactive coating that acts as the Li₊ insertion and extraction medium. In an embodiment, a complex Si/TiSi₂ hetero-nanostructure material of the present disclosure was fabricated using the following method steps: two-dimensional (2D) TiSi₂ nanonets were grown by reacting TiCl₄ and SiH₄ in H₂ using CVD, as described above. In brief, 50 sccm SiH₄ (10% in He), 2 sccm TiCl₄ and 100 sccm H₂ were fed into the growth chamber simultaneously. The receiving substrate was a Ti foil (Sigma, 0.127 mm). The reaction took place at about 675° C. The system was maintained at 5 Torr through out the growth, and growth occurred without growth seeds. After about fifteen minutes of reactions, the SiH₄ and TiCl₄ flows were stopped and the temperature was decreased to 650° C. while H₂ continued flowing. Afterwards, 80 sccm SiH₄ (10% in He) was introduced into the chamber to coat Si. The reaction was carried under 15 Torr total pressure at 650° C. for about twelve minutes and produced a uniform coating of Si nanoparticles of about 15 to about 20 nanometers in diameter on the TiSi₂ NNs. The resulting Si/TiSi₂ hetero-nanostructure material was then annealed in forming gas (5% H₂ in N₂) at 900° C. for about thirty seconds in a rapid thermal processor (RTP) to conclude the synthesis process.

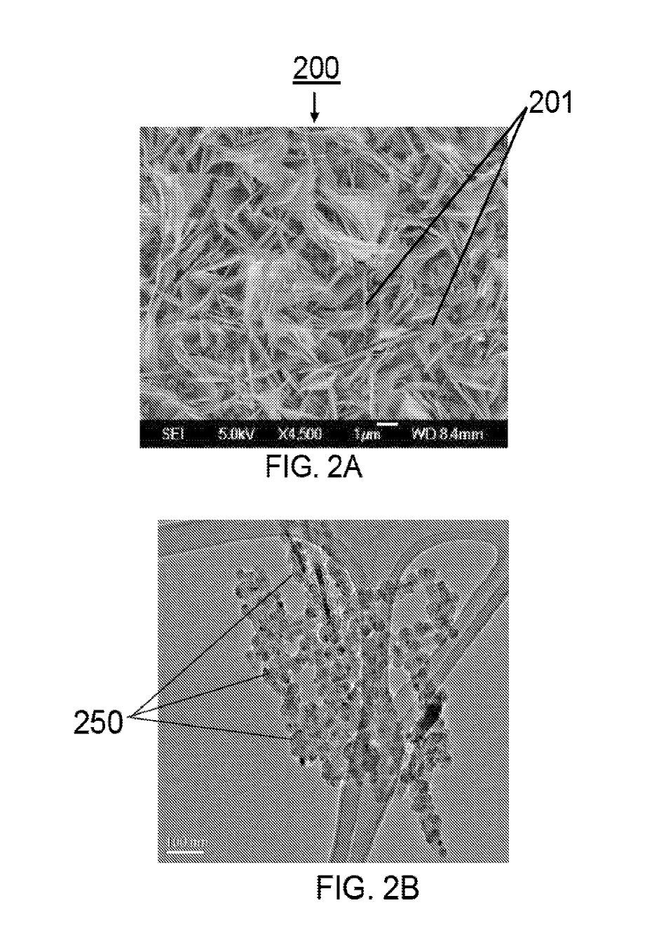

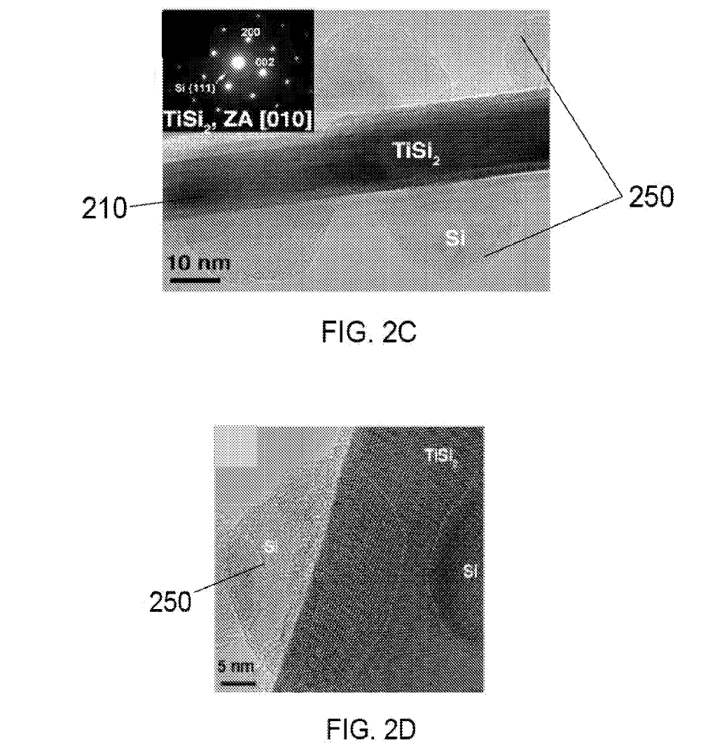

A scanning electron micrograph of the Si/TiSi₂ hetero-nanostructure material is shown in FIG. 2A. The hetero-nanostructure material is composed of a plurality of NNs. As illustrated in FIG. 2B, a transmission electron micrograph manifests the particulate nature of the Si coating on TiSi₂ NNs. Each NN has a structure made up of TiSi₂ nanobeam cores that are linked together by single crystalline junctions with about 90° angles, having a particulate Si coating on the TiSi₂ nanobeam cores. As illustrated in FIG. 2C, transmission electron microscopy (TEM) characterizations revealed that the Si nanoparticles grew epitaxially on TiSi₂. The crystallinity nature of the TiSi₂ nanobeam core and the particulate Si coating is shown in the lattice-resolved TEM of FIG. 2D.

After growth of the Si/TiSi₂ hetero-nanostructure material, a copper wire was attached to the Ti foil support substrate by conductive silver epoxy (SPI). The entire sample was then encapsulated by non-conductive epoxy (Loctite, hysol epoxi-patch adhesive) except the area where Si/TiSi₂ hetero-nanostructure material resided. The resulting working electrode was rolled together with a Li metal stripe counter electrode, separated by a polypropylene membrane (25 μm thick; Celgard 2500). Another Li metal stripe was used as the reference electrode. All electrodes were immersed in an electrolyte consisting of 1.0 M LiPF₆ in ethylene carbonate and diethyl carbonate (1:1; Novolyte Technologies). The electrochemical measurements were conducted in a sealed box that was located in an Ar-filled glovebox with the oxygen level <2 ppm.

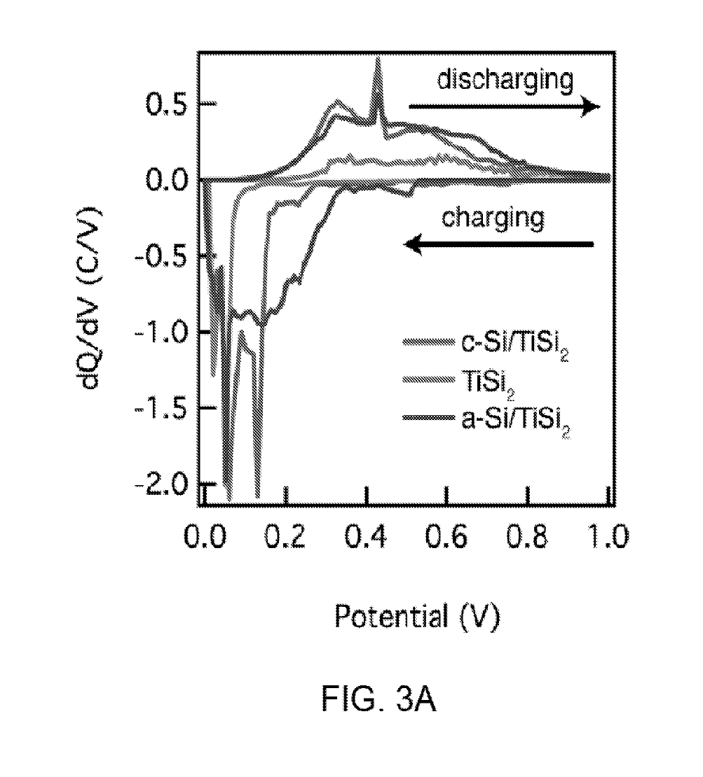

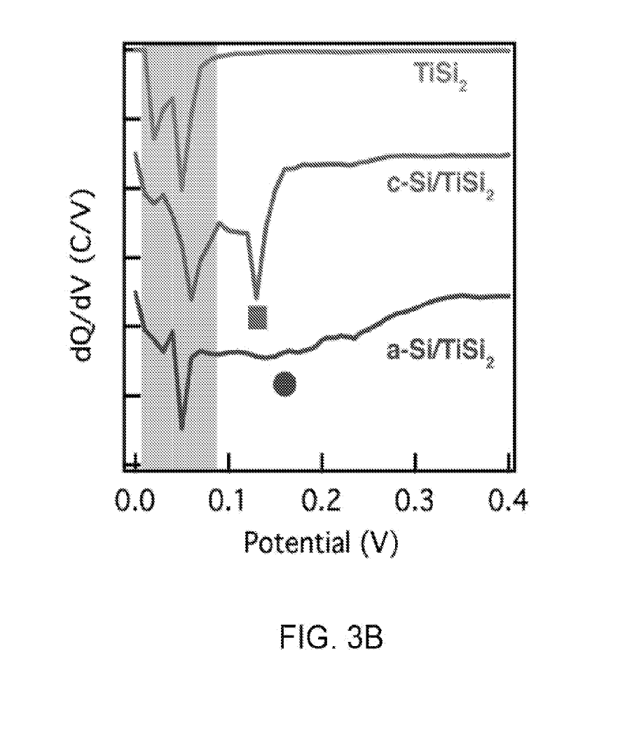

By limiting the state of charge (SOC) and discharge (SOD) through voltage control, experimental conditions were identified that allow for selective Li⁺ insertion into Si but not TiSi₂. As shown in FIGS. 3A and 3B, the peak in the photocapacitance spectra at 60 mV corresponds to Li⁺ reacting with TiSi₂ while that at 120 mV is caused by the reaction of Li⁺ with c-Si (see FIG. 3B). C-Si is typically transformed into amorphous Si (a-Si) after the first discharging, leading to a broad peak beginning at ˜240 mV.

A CHI 600C potentiostat/Galvanostat was used for all measurements reported here. The electrochemical cell was cooled to room temperature during the measurements. The applied potential of the Galvanostat was set between 3.00 V and varying cut-off voltages, e.g., 30 mV, 90 mV and 150 mV. In an embodiment, the applied potential could be set between 2.00 V and varying cut-off voltages, e.g., 30 mV, 90 mV and 150 mV. In an embodiment, the applied potential could be set between 3.00 V and varying cut-off voltages, e.g., 20 mV, 80 mV and 140 mV. The operation potential range for the first charging/discharging was set between 0.090-3.00 V to allow for sufficient lithiation of c-Si at a relatively slow rate of 1300 mA/g. The operation potential range was selected based on the difference between the electrochemical potential spectra of TiSi₂ and Si. A series of 10 mV potential steps were applied to the working electrode. At each step the current was allowed to decay to 200 mA/g. The total charges were obtained by integrating the measured current over time.

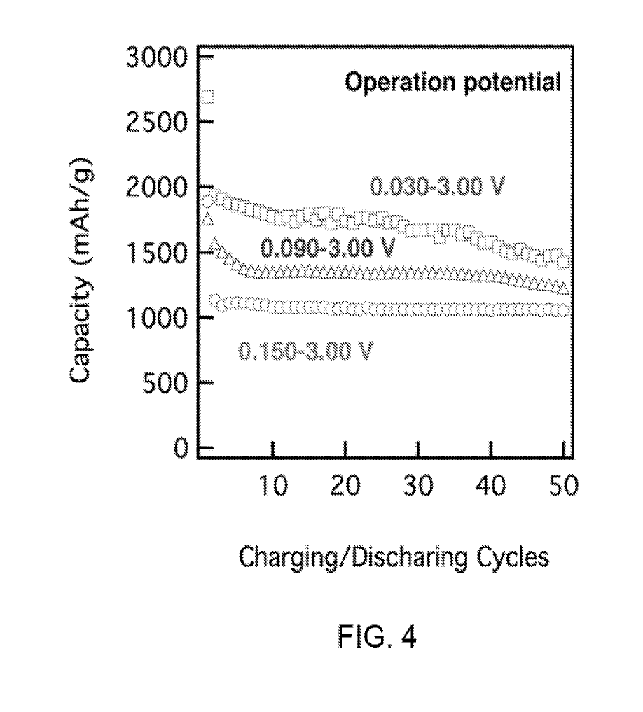

FIG. 4 illustrates how the range of operation potentials influences the capacity life of Si/TiSi₂ hetero-nanostructure materials. When the operation potentials were set between 0.150-3.00 V, no reactions occurred between TiSi₂ and the electrolyte. As a result, the capacity was maintained at a level of ˜1100 mAh/g during the first 50 cycles of charging/discharging. In contrast, when the operation potential range was increased to 0.090-3.00 V, the effect of the reactions between the electrolyte and TiSi₂ showed up. Although this reaction is less significant than that between Si and Li⁺, it nonetheless caused the degradation of TiSi₂, presumably due to stress-related pulverization, which manifested itself as a quick fading in the measured capacity after 40 cycles of charging/discharging. The effect of TiSi₂ degradation-induced capacity fading became more obvious when the operation potential range was further expanded to 0.030-3.00 V. Note that the higher stability at higher cut-off potentials was achieved at the expense of the specific capacity. For example, at the same charging/discharging rate (8400 mAh/g), the initial capacity measured with a 30 mV cut-off potential was ˜50% higher than measured with a 150 mV cut-off potential. Higher specific capacity was measured when slower charging/discharging rates were used. It should be understood that different charging/discharging rates can be applied to the hetero-nanostructure materials of the present disclosure. In an embodiment, the rate can be as high as 16.8 A/g.

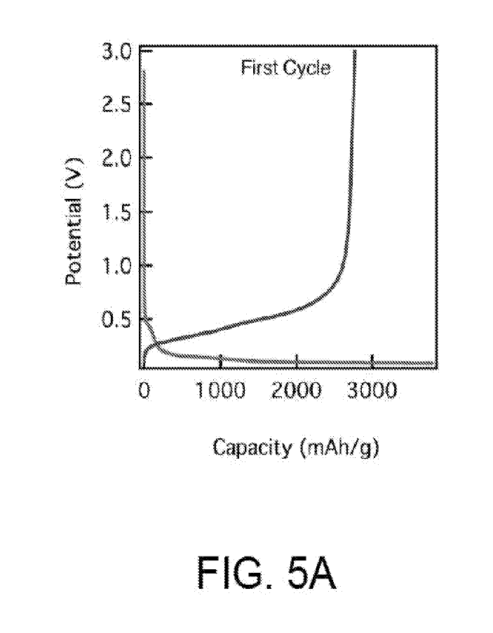

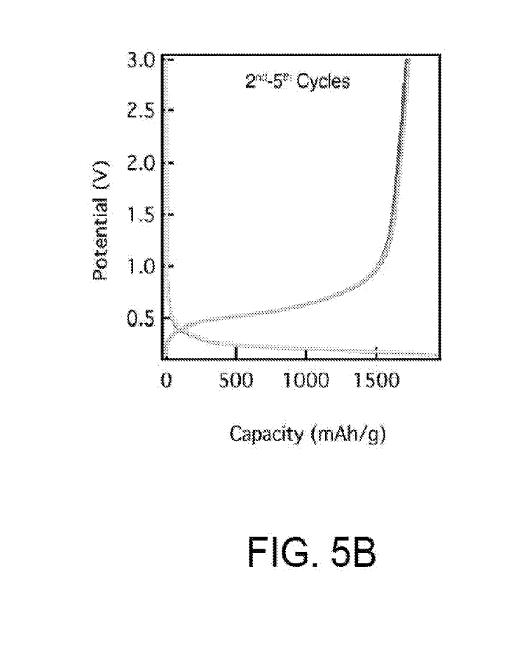

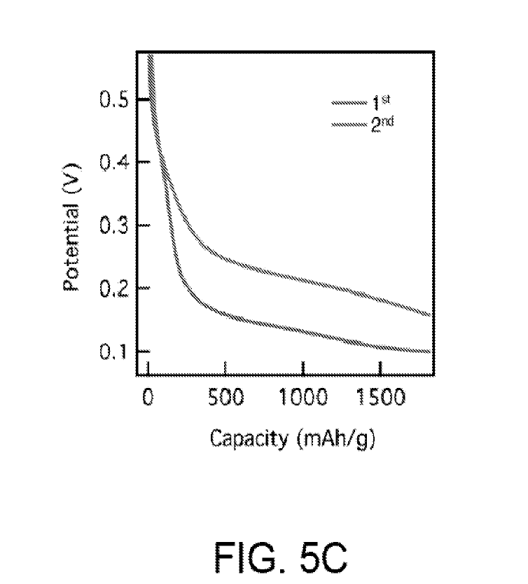

FIGS. 5A, 5B and 5C show the potential versus capacity curve of the first cycle (FIG. 5A), the second to the fifth cycles (FIG. 5B), and the first and the second cycles (FIG. 5C) for Si/TiSi₂ hetero-nanostructure materials of the present disclosure. Consistent with the electrochemical potential spectra of FIG. 3, a phase transition from c-Si to a-Si occurred during the first cycle charging/discharging process.

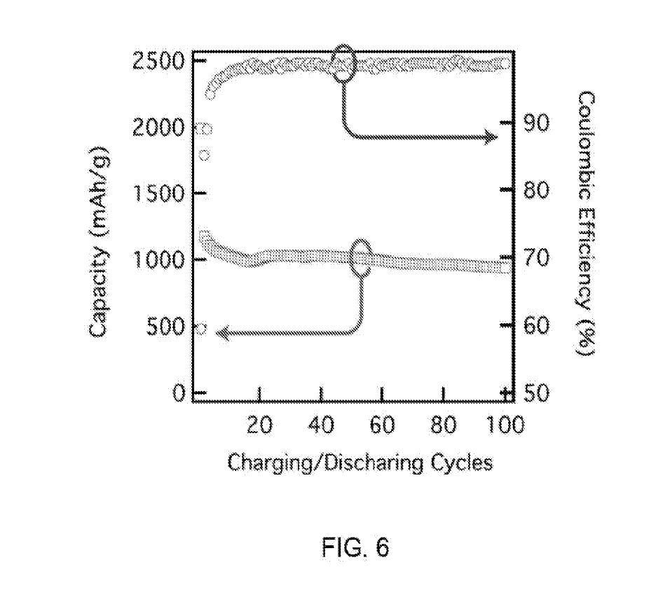

Experiments were conducted which involved cycling Si/TiSi₂ hetero-nanostructure material of the present disclosure between these limits at a rate of 2 C. The results over 100 cycles are shown in FIG. 6. Both the measured capacity and the Coulombic efficiency of each cycle are shown. The first charging capacity of 1990 mAh/g was obtained with a charging rate of 1300 mA/g. During this step, c-Si was converted to a-Si, and the phase transformation resulted in a large drop in the capacity upon discharge to 1182 mAh/g. Typically, this step is performed at a slow pace so as prevent rapid capacity fading as a result of pulverization. This reaction continued in the first 10 cycles as evident by the continuous capacity fade and the Coulombic efficiency increase. The capacity change after the first 10 cycles was minimum. For example, the charging capacity at the 23^{rd} cycle was 1026 mAh/g, and that at the 100^{th} cycle was 937 mAh/g, corresponding to a fade of 8.7%, or ˜0.1% per cycle.

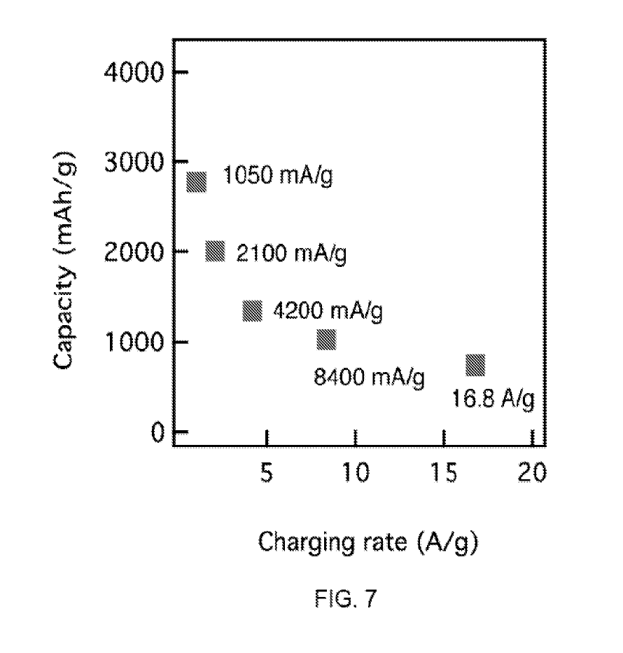

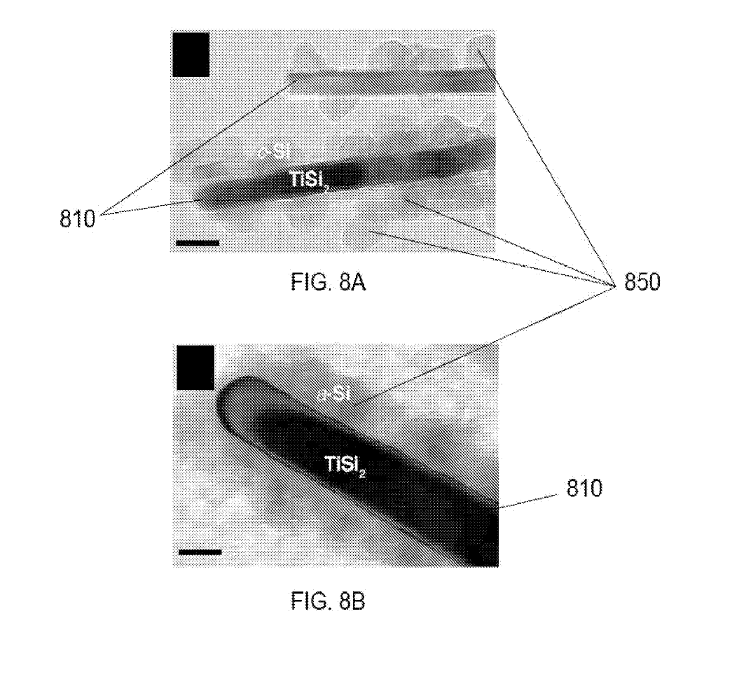

Consistent with literature reports, the specific capacity changes inversely with the charging/discharging rate, as illustrated in FIG. 7. As illustrated in FIG. 8A, the transmission electron micrograph (TEM) of the as-prepared Si/TiSi₂ hetero-nanostructure reveals the crystalline nature of both the TiSi₂ core and the Si shell. After 20 cycles of continuous charging/discharging, the Si shell is transformed into amorphous while the crystalline nature of the TiSi₂ core is preserved, as shown in FIG. 8B. Scale bars for both FIG. 8A and FIG. 8B are 20 nm.

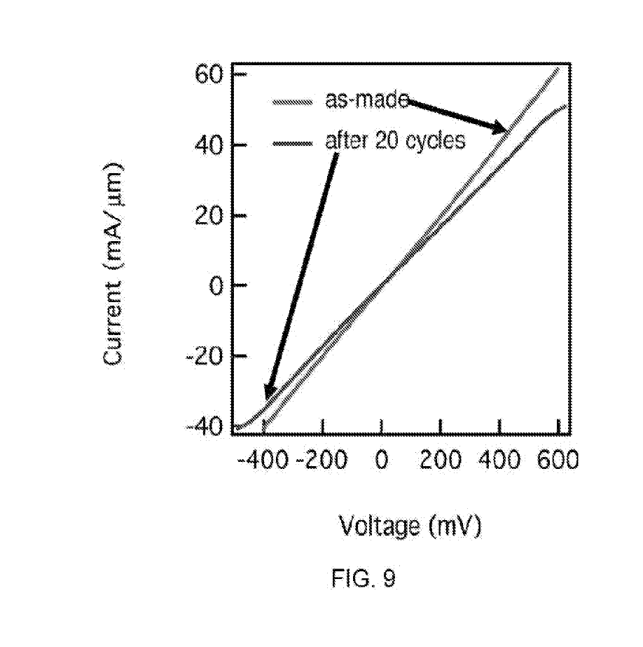

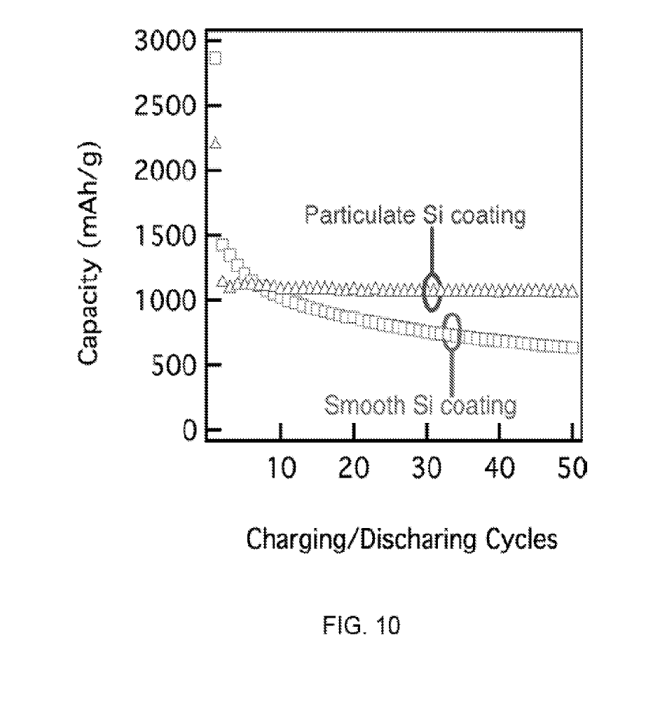

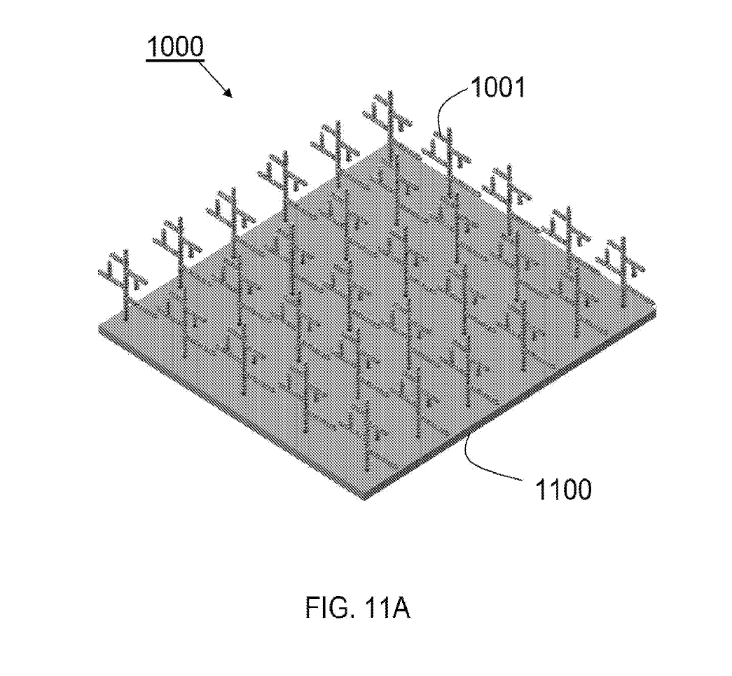

The conductivity of the TiSi₂ core at different stages of the charging/discharging processes was measured using a commercial STM-TEM sample holder (Nanofactory Instruments AB). The Si/TiSi₂ hetero-nanostructure material was attached to a sharp gold needle by gently dragging the needle on the surface of the working electrode. Another sharp gold probe was piezo-driven to make contact to the hetero-nanostructure material protruding from the gold needle, forming a two-terminal configuration. The measurement was conducted in a TEM (JOEL 2010F) chamber under vacuum conditions (P<10⁻⁹ Torr). As illustrated in FIG. 9, the superior conductivity of the TiSi₂ core also survives the charging/discharging processes. Both the crystallinity and the conductivity were preserved when the cut-off potential was set as 150 mV. The intact TiSi₂ core serves dual functionalities—structural support and charge transporter. Upon Li⁺ insertion, the TiSi₂ core provides electrons to counteract the cation-insertion-induced charge imbalance, allowing for rapid Li⁺ incorporation. Similarly, TiSi₂ also facilitates the electron collection and transport during Li⁺ extraction. The space between adjacent Si particles permits the volumetric expansion when the Li—Si alloy (e.g., Li₁₄Si₅) is formed. The nature of the coating has an impact on the capacity life of the resulting anode. Particulate Si coating, as that shown in FIGS. 2A-2C, allow for volumetric expansion upon Li⁺ insertion, yielding long capacity life. Uniform Si coating may lead to faster capacity fading due to the pulverization effect. Control experiments showed that the capacity faded more rapidly when a uniform Si coating was used (FIG. 10). In some embodiments, it may be desirable to use a uniform Si coating. In some embodiments, the thickness of the Si coating can be changed. In an embodiment, a thicker Si coating may lead to higher specific capacity, but poorer capacity life.

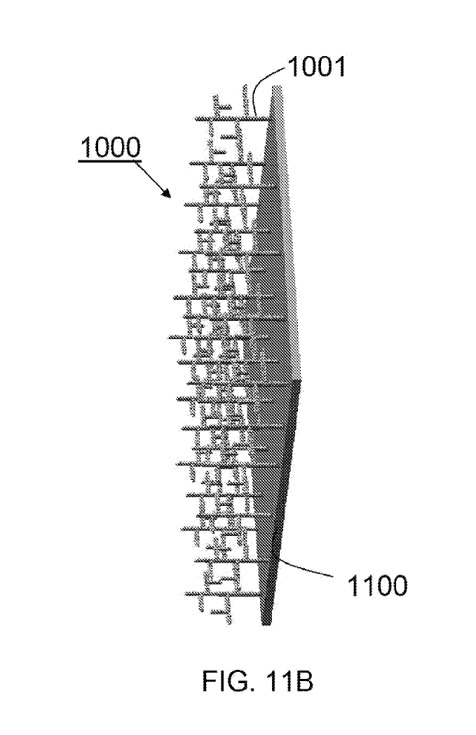

FIGS. 11A and 11B show schematic illustrations of an embodiment of a Si/TiSi₂ electrode 1000 of the present disclosure. FIG. 11A is a perspective view of the Si/TiSi₂ electrode 1000. FIG. 11B is a side view of the Si/TiSi₂ electrode 1000. The Si/TiSi₂ electrode 1000 is composed of a plurality of Si/TiSi₂ NNs 1001 formed on a surface of an electrode substrate 1100. In an embodiment, the electrode substrates 1100 on which the foregoing Si/TiSi₂ NNs 1001 is formed are those that can survive from the growth temperature, including, but not limited to, tungsten foil, silicon substrate and titanium foil. In an embodiment, the Si/TiSi₂ electrode 1000 is used as the anode material for a Li-ion battery. The lattice of Si and TiSi₂ are similar, so Si can combine with TiSi₂ easily, yielding interfaces desirable for efficient charge transport. Si and TiSi₂ have different lithiation potentials, making it possible to protect TiSi₂ during charging/discharging by choosing suitable potential ranges. The unique two-dimensional structure of the Si/TiSi₂ anode helps to transport charges more efficiently than nanowires or nanoparticles. The conductive silicide core functions as an inactive compound to support the silicone particulate coating and facilitate charge transport. The silicon particulate coating functions as an active component to store and release lithium-ion (Li⁺). The particulate nature of the Si coating accommodates its volumetric changes during lithiation, resulting in longer cycle life. The silicon particulate coating reacts with lithium-ions (Li⁺) to form Li—Si alloys, and spaces between the silicon particulate coating permits volumetric expansion when the Li—Si alloys are formed. In an embodiment, the Si/TiSi₂ anode can still hold (and release) power after hundreds of charges. A Si/TiSi₂ anode can be fabricated by performing chemical vapor deposition in a reaction chamber at a first temperature for a first period of time so as to fabricate TiSi₂ nanobeams, halting the flow of the one or more gas or liquid precursor materials while maintaining the carrier gas stream, cooling the reaction chamber to a second temperature, introducing the gas precursor back into the reaction chamber for a second period of time so as to coat the TiSi₂ nanobeams with silicon particulates. In an embodiment, ten times more charge can be stored by the Si/TiSi₂ anode as compared to a conventional graphite electrodes. In an embodiment, the high-performance Si/TiSi₂ anode can be paired with a cathode that can match. Although all of the Si/TiSi₂ nanonets 1001 forming the Si/TiSi₂ electrode 1000 are illustrated as being parallel to one another, it should be understood that the individual nanonets 1001 do not have to be in any particular order. An example of such an electrode is illustrated in FIG. 2A.

A method of fabricating a hetero-nanostructure material includes performing chemical vapor deposition in a reaction chamber at a first temperature for a first period of time so as to fabricate a two-dimensional conductive silicide, wherein one or more gas or liquid precursor materials carried by a carrier gas stream react to form a nanostructure having a mesh-like appearance and including a plurality of connected and spaced-apart nanobeams linked together at an about 90-degree angle; halting the flow of the one or more gas or liquid precursor materials while maintaining the carrier gas stream; cooling the reaction chamber to a second temperature; introducing the gas precursor back into the reaction chamber for a second period of time so as to coat the two-dimensional conductive silicide with particulates so as to fabricate the hetero-nanostructure material. In an embodiment, the conductive silicide is a titanium silicide. In an embodiment, the one or more gas or liquid precursor materials of the chemical vapor deposition is selected from a titanium containing chemical and a silicon containing chemical. In an embodiment, the carrier gas of the chemical vapor deposition is selected from the group consisting of H, HCl, HF, Cl₂, and F₂. In an embodiment, the particulates are silicon particulates. In an embodiment, the hetero-nanostructure material can be formed on a surface of an electrode substrate and used as a battery electrode.

All patents, patent applications, and published references cited herein are hereby incorporated by reference in their entirety. It will be appreciated that several of the above-disclosed and other features and functions, or alternatives thereof, may be desirably combined into many other different systems or application. Various presently unforeseen or unanticipated alternatives, modifications, variations, or improvements therein may be subsequently made by those skilled in the art.

What is claimed is:

1. A hetero-nanostructure material comprising a plurality of connected and spaced-apart nanobeams linked together at an about 90-degree angle, wherein the nanobeams are composed of a conductive silicide core having a particulate coating.

2. The hetero-nanostructure material of claim 1 further comprising a substrate, wherein the plurality of connected and spaced-apart nanobeams are supported on the substrate.

3. The hetero-nanostructure material of claim 1 wherein the conductive silicide core is made from a material selected from the group consisting of titanium silicide, nickel silicide, iron silicide, platinum silicide, chromium silicide, cobalt silicide, molybdenum silicide, and tantalum silicide.

4. The hetero-nanostructure material of claim 1 wherein the silicon particulate coating is made from a material selected from the group consisting of Si, Ge, SnO₂, TiO₂, MnO₂, WO₃, V₂O₅, CuO, NiO, Co₃O₄ and TiS₂.

5. The hetero-nanostructure material of claim 1 wherein the conductive silicide core is titanium silicide (TiSi₂) and the silicon particulate coating is Si.

6. The hetero-nanostructure material of claim 1 wherein the conductive silicide core functions as an inactive compound to support the silicone particulate coating and facilitate charge transport.

7. The hetero-nanostructure material of claim 1 wherein the silicon particulate coating functions as an active component to store and release lithium-ion (Li⁺).

8. An electrode comprising a plurality of Si/TiSi₂ nanonets formed on a surface of a supporting substrate, wherein each of the Si/TiSi₂ nanonets comprise a plurality of connected and spaced-apart nanobeams linked together at an about 90-degree angle, wherein the nanobeams are composed of a conductive silicide core having a silicon particulate coating.

9. The electrode of claim 8 capable of acting as an anode material for a lithium-ion battery.

10. The electrode of claim 8 wherein the conductive silicide core functions as an inactive compound to support the silicone particulate coating and facilitate charge transport.

11. The electrode of claim 8 wherein the silicon particulate coating functions as an active component to store and release lithium-ion (Li⁺).

12. The electrode of claim 8 wherein the silicon particulate coating reacts with lithium-ions (Li⁺) to form Li—Si alloys, and wherein spaces between the silicon particulate coating permits volumetric expansion when the Li—Si alloys are formed.

13. The electrode of claim 8 wherein the conductive silicide core is made from a material selected from the group consisting of titanium silicide, nickel silicide, iron silicide, platinum silicide, chromium silicide, cobalt silicide, molybdenum silicide, and tantalum silicide.

14. The electrode of claim 8 wherein the silicon particulate coating is made from a material selected from the group consisting of Si, Ge, SnO₂, TiO₂, MnO₂, WO₃, V₂O₅, CuO, NiO, Co₃O₄ and TiS₂.

15. A method of fabricating a hetero-nanostructure material comprising:
performing chemical vapor deposition in a reaction chamber at a first temperature for a first period of time so as to fabricate a two-dimensional conductive silicide, wherein one or more gas or liquid precursor materials carried by a carrier gas stream react to form a nanostructure having a mesh-like appearance and including a plurality of connected and spaced-apart nanobeams linked together at an about 90-degree angle;
halting the flow of the one or more gas or liquid precursor materials while maintaining the carrier gas stream;
cooling the reaction chamber to a second temperature; and
introducing the gas precursor back into the reaction chamber for a second period of time so as to coat the two-dimensional conductive silicide with particulates so as to fabricate the hetero-nanostructure material.

16. The method of claim 15 wherein the conductive silicide is a titanium silicide.

17. The method of claim 15 wherein the one or more gas or liquid precursor materials of the chemical vapor deposition is selected from a titanium containing chemical and a silicon containing chemical.

18. The method of claim 15 wherein the carrier gas of the chemical vapor deposition is selected from the group consisting of H, HCl, HF, Cl₂, and F₂.

19. The method of claim 15 wherein the particulates are silicon particulates.

20. The method of claim 15 wherein the two-dimensional conductive silicide is formed on a surface of a supporting substrate.
